(19) United States
(12) Patent Application Publication
(10) Pub. No.: US 2026/0201281 A1
(43) Pub. Date: Jul. 16, 2026

(54) SUBSTRATE TREATMENT SOLUTION

(71) Applicant: Merck Patent GmbH, Darmstadt (DE)

(72) Inventors: Yuki Kubo, Shizuoka (JP); Tatsuro Nagahara, Shizuoka (JP)

(21) Appl. No.: 19/137,199

(22) PCT Filed: Dec. 12, 2023
(86) PCT No.: PCT/EP2023/085279

§ 371 Date: Jun. 9, 2025

(30) Foreign Application Priority Data
Dec. 15, 2022 (JP) 2022-200253

(51) Int. Cl. C11D 7/26; B08B 3/08; C11D 7/28; C11D 7/32; C11D 7/34; C11D 7/50; H10P 70/00

(52) U.S. Cl. CPC C11D 7/261; B08B 3/08; C11D 7/265; C11D 7/267; C11D 7/28; C11D 7/3209; C11D 7/34; C11D 7/5022; H10P 70/20

(57) ABSTRACT

A substrate treatment solution including a solidification component, wherein at least either the following condition (i) or condition (ii) is satisfied: (i) the solidification component is a plastic crystal compound having a melting point of 20° C. or more and 200° C. or less, and (ii) the substrate treatment solution further includes a surface modification component.

### BACKGROUND OF THE INVENTION

### Technical Field

An embodiment of the present invention relates to a substrate treatment solution.

### Background Art

In the manufacture of devices (electronic parts) such as semiconductor devices and liquid crystal display devices, a process for forming a fine uneven pattern on a wafer surface by film formation, lithography, or etching, etc. and then cleaning the wafer surface is known. Due to the needs for higher integration of LSI, devices tend to be micronized, and there are needs for making the width of the uneven pattern as described above narrower and making the aspect ratio higher. For cleaning the wafer surface on which the uneven pattern is formed, a technique for removing contaminants by supplying a cleaning liquid such as deionized water (DIW) or an organic solvent is known. However, if the uneven pattern is very fine, there is a problem that pattern collapse occurs due to the surface tension and capillary action of the cleaning liquid during the drying process after removing the contaminants.

Under such circumstances, there is an attempt to clean the pattern while preventing the pattern collapse by replacing the cleaning liquid or the like in the cleaning process with a filling treatment agent containing a sublimable substance, and then sublimating the sublimable substance. Patent Document 1 discloses a technique in which a substrate treatment solution containing plastic crystals is applied to the substrate and cooled to semi-solidify to form a plastic crystal layer, and the plastic crystal layer is removed by vaporization to remove the liquid attached to the surface of the substrate while preventing pattern collapse. Patent Document 2 discloses a technique in which cyclohexanone oxime is included as a sublimable substance in a substrate treatment solution, and the liquid attached to the surface of the substrate is removed while preventing pattern collapse. Patent Document 3 provides a pattern forming method using a gap filling compound.

### PRIOR ART DOCUMENTS

### Patent Documents

[Patent Document 1] JP 2019-62004
[Patent Document 2] JP 2021-10002
[Patent Document 3] WO 2017/174476

### Non-Patent Document

[Non-Patent Document 1] Toshiba Review Vol. 59 No. 8 (2004), pp. 22-25

### SUMMARY OF THE INVENTION

### Problems to be Solved by the Invention

The present inventors considered that there are one or more problems that still need improvements. These include, for example, the following. The substrate pattern cannot be cleaned cleanly. The pattern collapse occurs during cleaning of the substrate pattern. The fine substrate pattern cannot be filled. The film cannot be formed on the fine substrate pattern. The film cannot be formed without cooling. Pressure reduction is required to remove the film. It is difficult to first vaporize the solvent and then vaporize the solidification component stepwise. The amount of the solidification component that remains in the substrate pattern after removal is large. The solubility of the solidification component in the solvent is low. The step for removing the film from the process of cleaning the substrate pattern is complicated. There is damage to other layers and structures around the substrate pattern during substrate pattern cleaning. The yield is poor. The stability of the substrate treatment solution is low. There is a large amount of film remaining after the film formed from the substrate treatment solution is removed. Cracks occur in the film formed from the substrate treatment solution. The pattern collapse occurs when the thickness of the film formed from the substrate treatment solution is increased.

In view of the above-mentioned problems, one object of an embodiment of the present invention is to provide a substrate treatment solution that can improve suppression of pattern collapse.

### Means for Solving the Problems

A substrate treatment solution according to an embodiment of the present invention includes a solidification component. At least either the following condition (i) or condition (ii) is satisfied:
(i) the solidification component is a plastic crystal compound having a melting point of 20° C. or more and 200° C. or less, and
(ii) the substrate treatment solution further comprises a surface modification component represented by the following general formula (I).

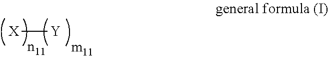

In the general formula (I), X is each independently one of the group consisting of a tertiary amine, a secondary amine, a primary amine, —OH, —SO₂—NH—SO₂—, —CO—NH₂, —COOH, —CHO, —SO₃H, —CO—NH—CO—, and —CO—NH—SO₂—. Y is each independently H, fluoroalkyl having C₁₋₁₀, or fluoroaryl having C₅₋₂₀. At least one of Y is fluoroalkyl having C₁₋₁₀ or fluoroaryl having C₅₋₂₀. n₁₁ is 1, 2 or 3. m₁₁ is 1, 2 or 3. At least one of n₁₁ and m₁₁ is 1.

The substrate treatment solution is not cooled above a temperature that is 5° C. lower than a freezing point of the solidification component and in a temperature range below the freezing point of the solidification component.

The solidification component may have a molecular weight of 58 or more and 200 or less.

A content of the solidification component may be 1% by mass or more and 50% by mass or less based on the substrate treatment solution.

A content of the surface modification component is 0.01% by mass or more and 1.0% by mass or less based on the substrate treatment solution.

The substrate treatment solution further includes a solvent. The solvent may include an organic solvent comprising at least one selected from the group consisting of alcohols, alkanes, ethers, lactic esters, acetic esters, aromatic hydorocarbons, ketones, amides, and lactones, and/or a water.

The substrate treatment solution may be used for replacing a cleaning liquid that remains on the substate when a substrate pattern on the substrate is cleaned with the cleaning liquid.

In an embodiment of the invention, a film is formed using the substrate treatment solution, and then the film is removed from a substrate pattern by vaporizing the solidification component. The vaporization is preferably a sublimation. The vaporization may be performed by at least one step selected from the group consisting of heating a substrate, blowing a gas, and rotating the substrate when the film formed using the substrate treatment solution is removed.

A substrate treatment solution according to the present invention is applied on a pattern of a substrate to form a film, and a thickness T of the film and a height H of the pattern satisfy a relational equation 1H≤T≤5H.

### Effects of the Invention

Using the substrate treatment solution according to an embodiment of the present invention, it is possible to obtain one or more of the following effects.

It is possible to cleanly clean the substrate pattern. It is possible to suppress pattern collapse during cleaning of the substrate pattern. It is possible to fill the fine substrate pattern. It is possible to form the film on the fine substrate pattern. It is possible to form the film without cooling. It is possible to remove the film without pressure reduction. It is possible to suppress pattern collapse by vaporizing the solvent first and then vaporizing the solidification component stepwise. It is possible to reduce the amount of the solidification component that remains in the substrate pattern after removal. It is possible to obtain the substrate treatment solution having good solubility of the solidification component in the solvent. It is possible to reduce the steps for removing the film from the process of cleaning the substrate pattern. It is possible to reduce damage to other layers and structures around the substrate pattern. The yield is good. The stability of the substrate treatment solution is good. The plastic crystal layer can be formed from the substrate treatment solution. The amount of remaining film can be reduced after the film formed from the substrate treatment solution is removed. It is possible to form the film with high toughness from the substrate treatment solution. It is possible to reduce cracks in the film formed from the substrate treatment solution. Pattern collapse does not occur even when the thick film is formed from the substrate treatment solution.

### BRIEF DESCRIPTION OF THE DRAWINGS

FIG. 1 is a schematic cross-sectional view illustrating a method for forming a substrate pattern using a substrate treatment solution according to an embodiment of the present invention.

### DETAILED DESCRIPTION OF THE INVENTION

A substrate treatment solution according to an embodiment of the present invention is described below.

### Definitions

Unless otherwise specified in the present specification, the definitions and examples described in this paragraph are as follows.

The singular form includes the plural form and “one” or “that” means “at least one”. An element of a concept can be expressed by a plurality of species, and when the amount (for example, mass % or mol %) is described, it means the sum of the plurality of species.

“And/or” includes a combination of all elements and also includes single use of the element.

When a numerical range is indicated using “to”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has plural types of repeating units, these repeating units copolymerize. These copolymerizations may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, the compound itself that generates a base). An aspect in which the compound is dissolved or dispersed in a solvent and added to the composition is also possible. It is preferable that such a solvent is contained in the substrate treatment solution as a solvent (C) or an other additive, which is described later.

### [1. Composition of Substrate Treatment Solution]

The substrate treatment solution according to an embodiment of the present invention includes a solidification component (A), a surface modification component (B), a solvent (C), a vaporization component (D), and an other additive (E). In addition, the surface modification component (B), the vaporization component (D), and the other additive (E) may be included in the substrate treatment solution as necessary. The substrate treatment solution is preferably a pattern filling substrate treatment solution, and is used in a cleaning process of a substrate pattern.

Here, a substrate pattern in the present specification includes a pattern formed by processing the surface of a substrate. The substrate pattern preferably does not include a pattern formed from other films or layers on the substrate. For example, it is preferable that a pattern in which a resist pattern made only of an organic substance is formed on a bare wafer is not included in the substrate pattern. However, a pattern obtained by depositing metal to form a metal film on the surface of the substrate and processing the metal film is included in the substrate pattern. The surface of the substrate before being processed may be treated with oxygen or nitrogen. A resist pattern containing substances other than organic substances may or may not be included in the substrate pattern of the present invention (more preferably, it may not be included). The resist pattern containing substances other than organic substances can be formed using a solidification component containing Si or Sn (preferably a matrix, more preferably a resin) as a resist composition. It is considered that a resist pattern formed with such a resist composition has high hardness and can therefore be used as the substrate pattern using the substrate treatment solution of the present invention.

The substrate treatment solution refers to a composition that is filled (overflow is allowed) into a gap in the substrate pattern, and an aspect in which a film is formed afterwards is more preferable.

In the following description, each component of the substrate treatment solution is described.

### [1-1. Solidification Component (A)]

The substrate treatment solution according to an embodiment of the present invention includes a solidification component, and in one aspect, (i) the solidification component is preferably a plastic crystal compound having a melting point of 20° C. or more and 200° C. or less at room temperature.

The substrate treatment solution according to an embodiment of the present invention is filled into a substrate pattern to form a film. The solvent (C) is first vaporized, the solidification component (A) forms a film, and then the film is removed by vaporizing the solidification component (A). A preferred aspect of vaporization is sublimation. Preferably, sublimation is a direct change of a part of the solidification component (A) from the solid phase to the gas phase. More preferably, sublimation is a direct change of substantially all of the solidification component (A) from the solid phase to the gas phase. Further, in another aspect of the solidification component (A), the solidification component (A) is a substance having a sublimation point that changes from a solid phase to a gas phase without passing through a liquid phase at room temperature. In another preferred aspect, the solidification component (A) may be a substance that changes from a solid phase to a gas phase through a liquid phase when the solidification component (A) is heated at ambient pressure, has a melting point, and sublimates slowly below the melting point.

When removing the film formed by the substrate treatment solution, the substrate may be heated. The heating referred to here is more preferably performed at 40° C. or higher, further preferably at 50° C. or higher, further more preferably at 60° C. or higher. The upper limit is more preferably 200° C. or less, further preferably 170° C. or less, further more preferably 150° C. or less. Another advantage of the present invention is that when removing the above-mentioned film in the present invention, the cooling step as described in Patent Document 1 is not essential. In another aspect, the film may be removed by spraying a gas or by rotating the substrate. The gas referred to here includes air, Ar, and nitrogen gas, and for example, a gas in which humidity and oxygen concentration are reduced is used. In addition, it is also a preferred aspect of the present invention not to apply reduced pressure (in particular, 80 kPa or less) to remove the film.

From the viewpoint of making the substrate pattern clean and reducing the amount remaining on the substrate pattern, it is desirable that the solidification component (A) is a substance that is easily vaporized. In order to further reduce the remaining amount of the solidification component (A) having such characteristics, it is also possible to add a heating step. In an embodiment of the present invention, it is possible to perform heating when the film formed from the substrate treatment solution is removed, and the conditions therefor can be 35 to 150° C. (preferably 35 to 120° C., more preferably 40 to 110° C., particularly preferably 40 to 100° C.), and for 10 to 180 seconds (preferably 10 to 120 seconds, more preferably 10 to 90 seconds).

In one embodiment of the present invention, it is preferable that the substrate treatment solution is not cooled above a temperature that is 5° C. lower than the freezing point of the solidification component (A) and below a temperature of the freezing point of the solidification component (A). The solidification component (A) is preferably a substance having such a freezing point. For example, the solidification component (A) has a melting point at ambient pressure of 20 to 200° C., preferably 25 to 190° C., more preferably 30 to 180° C., further more preferably 30 to 100° C. In this case, since the film formed with the substrate treatment solution is solid at room temperature (25° C.), it does not require a cooling device and is easy to handle.

Although not to be bound by theory, when the substrate treatment solution is cooled above a temperature that is 5° C. lower than the freezing point of the solidification component (A) and below a temperature of the freezing point of the solidification component (A), the number of processes in the substrate treatment increases and the cost and time are increased. Further, condensation may occur from the gas in the system, and the case where the condensed water droplets cause pattern collapse and generate defects on the wafer is undesirable.

The concentration of the solidification component (A) is 1 to 50% by mass (preferably 1 to 30% by mass, more preferably 2 to 20% by mass) based on the substrate treatment solution. Although the concentration of the solidification component (A) is not particularly limited, it is difficult to form a film and the effect of suppressing pattern collapse is reduced when the amount of the solidification component (A) is too small. Therefore, the above range is preferred.

The solidification component (A) has a molecular weight of 58 to 200 (preferably 70 to 180). Although the molecular weight of the solidification component (A) is not particularly limited, energy is required during vaporization when the molecular weight is too large. Therefore the above range is preferable.

When the solidification component included in the substrate treatment solution according to an embodiment of the present invention does not satisfy the above condition (i) but satisfies the above condition (ii), it is preferable that the solidification component (A) is a vaporization component (D). In particular, the above-mentioned vaporization component (D) functions as a solidification component and is removed by vaporization, and the vaporized component (D) is included in the substrate treatment solution together with the surface modification component (B).

The solidification component (A) is preferably a plastic crystal, more preferably a plastic molecular crystal. The plastic crystal is a substance with soft properties, and has a plastic crystalline phase as an intermediate phase between a crystalline phase and a liquid phase. In particular, the structure of the solidification component (A) is as follows. However, the structure of the solidification component (A) is not limited to the following structure.

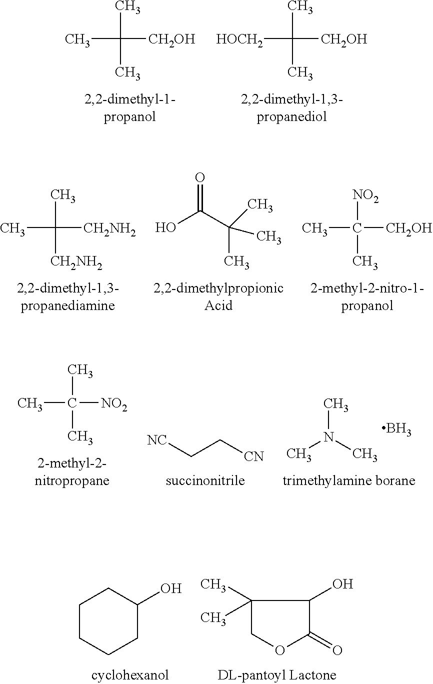

### [1-2. Surface Modification Component (B)]

The substrate treatment solution according to one embodiment of the present invention may contain a surface modification component (B). The surface modification component (B) is a compound that can be physically adsorbed onto the surface of the substrate. It is preferable that the surface modification component (B) has highly volatility. In particular, although the surface modification component (B) is preferably vaporized when the solidification component (A) is vaporized, or before or after the vaporization, the surface modification component (B) is not limited thereto. The content of the surface modification component (B) included in the substrate treatment solution is 0.01 to 1.0% by mass, preferably 0.02 to 0.2% by mass, more preferably 0.03 to 0.2% by mass, based on the substrate treatment solution. In addition, in one embodiment of the present invention, there may be an aspect in which the surface modification component (B) is not included (0% by mass) in the substrate treatment solution.

In an aspect of the present invention, the substrate treatment solution includes (ii) a surface modification component represented by the general formula (I) in addition to the solidification component. Formula (I) is described later.

The surface modification component (B) is preferably a repellent. Although not to be bound by theory, it is considered that in an aspect of the present invention, the surface modification component (B) is adsorbed to the surface of the pattern and causes repulsion between the patterns, thereby further preventing pattern collapse.

A silicon coupling agent is generally known as a surface modifier. However, since a silicon coupling agent reacts with water and alcohol, water and alcohol cannot be used as a solvent. Further, since the silicon coupling agent forms a chemical bond with the substrate surface, that is, so-called chemical adsorption, a process such as ashing to break the bond is required when the silicon coupling agent is removed. Although not to be bound by theory, since the surface modification component (B) included in the substrate treatment solution is physically adsorbed, many types of solvents can be used, such as the solvent (C), which is described below. It is also possible to remove the surface modification component (B) when the solidification component (A) is vaporized, and in this case, a process for removing only the surface modification component (B) is not required.

For example, the surface modification component (B) is a compound represented by the general formula (I).

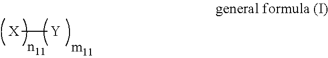

Here, in the general formula (I), X is each independently one of the group consisting of a tertiary amine, a secondary amine, a primary amine, —OH, —SO₂—NH—SO₂—, —CO—NH₂, —COOH, —CHO, —SO₃H, —CO—NH—CO—, and —CO—NH—SO₂—. X is each independently preferably a tertiary amine, a primary amine, —OH, —SO₂—NH—SO₂—, —CO—NH₂, —COOH, —CHO, —SO₃H, —CO—NH—CO—, or —CO—NH—SO₂—, more preferably a tertiary amine, —OH, or —SO₂—NH—SO₂—, further more preferably —OH.

Further, in the general formula (I), Y is each independently H, fluoroalkyl having C₁₋₁₀, or fluoroaryl having C₅₋₂₀, and at least one of Y is fluoroalkyl having C₁₋₁₀ or fluoroaryl having C₅₋₂₀. Here, the fluoroalkyl is an alkyl in which some or all of H is replaced with fluoro (preferably, all of H in an alkyl are replaced with fluoro.). Here, the fluoroaryl is an aryl in which some or all of H is replaced with fluoro (preferably, all of H in an aryl are replaced with fluoro.). A preferred example of fluoro is F or Cl (a more preferred example is F.). Y is each independently preferably H, fluoroalkyl having C₁₋₉ or fluoroaryl having C₆, more preferably fluoroalkyl having C₂₋₄.

Further, n₁₁ is 1, 2 or 3, m₁₁ is 1, 2 or 3, and at least one of n₁₁ and m₁₁ is 1. Preferably n₁₁ is 1 and m₁₁ is 1, 2, or 3, more preferably n₁₁ and m₁₁ are 1.

In addition, a tertiary amine, a secondary amine, and a primary amine are as follows.

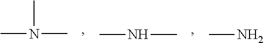

Furthermore, X may be a polar functional group. In one compound represented by the general formula (I), the sum of the valences of X is equal to the valences of Y. For example, X is an m₁₁-valent polar functional group when n₁₁=1, and the number of m₁₁ is determined by the selected X.

In particular, the structure of the surface modification component (B) is as follows. However, the surface modification component (B) is not limited to the following structures.

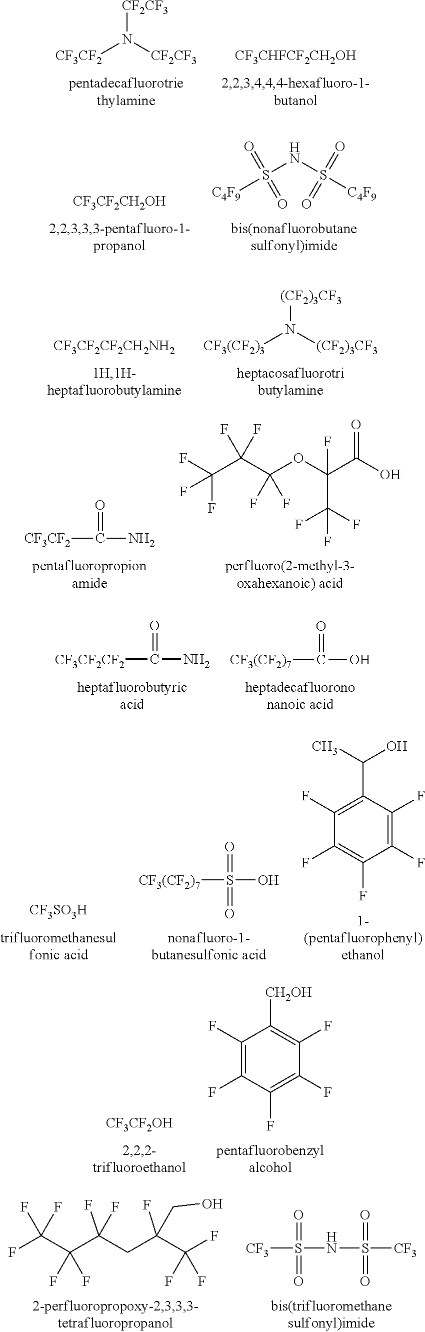

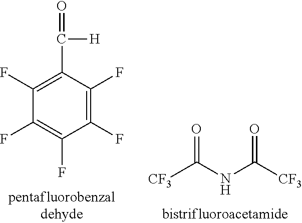 [SMILES: O=Cc1c(F)c(F)c(F)c(F)c1F ; O=C(NC(=O)C(F)(F)F)C(F)(F)F]

### [1-3. Solvent (C)]

The substrate treatment solution according to an embodiment of the present invention includes a solvent (C). It is preferable that the solvent (C) can dissolve at least a portion of the solidification component (A) and is volatile. The boiling point of the solvent (C) at 1 atm is 50 to 200° C., preferably 60 to 170° C., more preferably 70 to 150° C. Further, the solvent (C) is a solvent that is vaporized by spin drying. The content of the solvent (C) is 30 to 99% by mass, preferably 50 to 95% by mass, more preferably 80 to 95% by mass, particularly preferably 85 to 95% by mass.

For example, water and/or an organic solvent can be used as the solvent (C). The solvent (C) may be a mixture of water and an organic solvent. The water is preferably pure water (Deionized water: DIW). In an aspect of the invention, the solvent (C) is water. When the solvent (C) is water, the amount of organic solvent used can be reduced, which is considered to be advantageous in terms of the process.

When the solvent (C) is a mixture of water and an organic solvent, the volume ratio thereof is 1:99 to 99:1, preferably 10:90 to 90:10, more preferably 20:80 to 80:20, and further more preferably 40:60 to 60:40.

For example, alcohols such as methanol (MeOH), ethanol (EtOH), 1-propanol, isopropanol (IPA), 1-butanol, benzyl alcohol, and the like, alkanes such as hexane, heptane, and octane, ethyl butyl ether, and the like, ethers such as butyl ether, tetrahydrofuran (THF), anisole, and the like, lactic acid esters such as methyl lactate, ethyl lactate (EL), and the like, acetate esters such as ethyl acetate, butyl acetate, and the like, aromatic hydrocarbons such as benzene, toluene, xylene, and the like, ketones such as acetone, methyl ethyl ketone, methyl isobutyl ketone, 2-heptanone, cyclopentanone, cyclohexanone, and the like, amides such as N,N-dimethylacetamide, N-methylpyrrolidone, and the like, or lactones such as γ-butyrolactone and the like can be used as the organic solvent. In addition to the above-mentioned compounds, ethylene glycol monoalkyl ethers such as ethylene glycol monomethyl ether, ethylene glycol monoethyl ether, and the like, ethylene glycol monoalkyl ethers such as ethylene glycol monomethyl ether acetate, ethylene glycol monoethyl ether acetate, and the like, propylene glycol monoalkyl ethers such as propylene glycol monomethyl ether (PGME), propylene glycol monoethyl ether (PGEE), and the like, propylene glycol monoalkyl ether acetate such as propylene glycol monomethyl ether acetate (PGMEA), propylene glycol monoethyl ether acetate, and the like can be used as the organic solvent. These organic solvents can be used alone or in combination of two or more.

Here, one preferred aspect of the organic solvent included in the substrate treatment solution is particularly described.

The organic solvent included in the solvent (C) is one or more selected from the group consisting of MeOH, EtOH, 1-propanol, IPA, 1-butanol, THF, PGEE, PGME, PGMEA, benzene, acetone, methyl isobutyl ketone, cyclopentanone, cyclohexanone, ethyl acetate, butyl acetate, EL, dibutyl ether, anisole, and benzyl alcohol. Further, the organic solvent included in the solvent (C) is preferably one or more selected from the group consisting of MeOH, EtOH, IPA, PGEE, and acetone. Furthermore, the organic solvent included in the solvent (C) is more preferably one or more selected from the group consisting of MeOH, EtOH, IPA, and PGEE. When the organic solvent is a combination of two types, the mass ratio is 1:99 to 99:1, preferably 10:90 to 90:10, more preferably 20:80 to 80:20, further more preferably 40:60 to 60:40.

### [1-4. Vaporization Component (D)]

The substrate treatment solution according to an embodiment of the present invention may further include a vaporization component (D). The vaporization component (D) is a component that remains as a solidification component in a film formed from the substrate treatment solution and can be vaporized. The vaporization component (D) is preferably a component different from the plastic crystal compound having a melting point of 20° C. or more and 200° C. or less at room temperature, and more preferably a component different from the solidification component (A). The content of the vaporized component (D) included in the substrate treatment solution is 0 to 20% by mass with respect to the substrate treatment solution. The upper limit of the content is preferably 15% by mass, more preferably 10% by mass, further preferably 5% by mass, and further more preferably 2% by mass. The lower limit of the content is preferably 0% by mass, more preferably 0.1% by mass, and further more preferably 0.5% by mass. It is also a preferred aspect of the present invention that the vaporization component (D) is not included (0% by mass). When the solidification component included in the substrate treatment solution according to an embodiment of the present invention does not satisfy the above condition (i) but satisfies the above condition (ii), and the solidification component (A) is a vaporization component (D), the description of the solidification component (A) above takes precedence over the content of the solidification component (B).

For example, the vaporization component (D) is a compound such as a saturated hydrocarbon ring. In particular, the vaporization component (D) is a compound represented by the general formula (II).

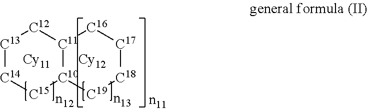

Cy₁₁ and Cy₁₂ are each independently a saturated or unsaturated hydrocarbon ring or heterocyclic ring. Preferably Cy₁₁ and Cy₁₂ are both saturated or unsaturated hydrocarbon rings or heterocyclic rings, more preferably both Cy₁₁ and Cy₁₂ are both saturated hydrocarbon rings or heterocyclic rings. The heterocyclic ring referred to here may be a heterocyclic ring obtained as a result of replacing Cⁿ¹ that forms the ring.

Cⁿ¹ is each carbon, and n1 is an integer from 10 to 19 (i.e., C¹⁰, C¹¹, . . . C¹⁹). The remaining bonding hand of Cⁿ¹ is bonded with H.

Cⁿ¹ may be each independently replaced with —Cⁿ¹Rₙ₁—, —Cⁿ¹Rₙ₁Rₙ₁—, —Cⁿ¹(OH)—, —Cⁿ¹(═O)—, —Nⁿ¹H—, and/or —Nⁿ¹Rₙ₁—. However, at least one of Cⁿ¹ is replaced by at least one of the above substituents. It goes without saying that elements that do not exist are excluded from the conditions of this proviso. For example, in the case of n₁₁=n₁₂=0, at least any one of C¹⁰ to C¹⁴ is replaced. It is preferred that adjacent Cⁿ¹ are not replaced at the same time.

Rₙ₁ and Rₙ₁ are each independently C₁₋₅ alkyl (preferably C₁₋₄, more preferably C₁₋₃), —NH₂ and/or C₁₋₅ aminoalkyl (preferably C₁₋₄, more preferably C₁₋₃, further preferably C₁), and Rₙ₁ and/or Rₙ₁ may be combined with another Rₙ₁, Rₙ₁ and/or Cₙ₁ to form a ring. It is a preferred aspect that Rₙ₁ and Rₙ₁ are combined with another Rₙ₁, Rₙ₁ and/or Cⁿ¹ to form a ring.

n11, n12 and n13 are each independently 0 or 1. Preferably n₁₁=0. Preferably n₁₂=1. Preferably n₁₃=1.

Further, the vaporization component (D) may be two or more kinds of compounds. In this case, the vaporization component (D) may include the compound represented by the general formula (III) as well as the compound represented by the general formula (II).

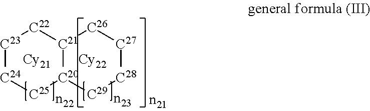

The definitions, examples, and descriptions of Cy₂₁, Cy₂₂, Rₙ₂, Rₙ₂, n₂₁, n₂₂ and n₂₃ are each independently the same as those of Cy₁₁, Cy₁₂, Rₙ₁, Rₙ₁, n₁₁, n₁₂ and n₁₃.

The definitions, examples, and descriptions of Cⁿ² are each independently the same as those of Cⁿ¹. n2 is an integer from 20 to 29 (i.e., C²⁰, C²¹, . . . C²⁹). Examples and descriptions of n2 (20-29) each independently correspond to those of n1 (10-19).

Although the scope of the present invention is not limited, particular examples of the vaporization component (D) include the following compounds. That is, the vaporization component (D) is each independently phthalic anhydride, caffeine, melamine, 1,4-benzoquinone, camphor, hexamethylenetetramine, hexahydro-1,3,5-trimethyl-1,3,5-triazine, 1-adamantanol, 1,4-diazabicyclo[2.2.2]octane, borneol, (−)-borneol, (±)-isoborneol, 1,2-cyclohexanedione, 1,3-cyclohexanedione, 1,4-cyclohexane dione, 3-methyl-1,2-cyclopentanedione, (±)-camphorquinone, (−)-camphorquinone, (+)-camphorquinone, or 1-adamantanamine.

Although the scope of the present invention is not limited, particular examples of the vaporization component (D) are shown below in terms of structure.

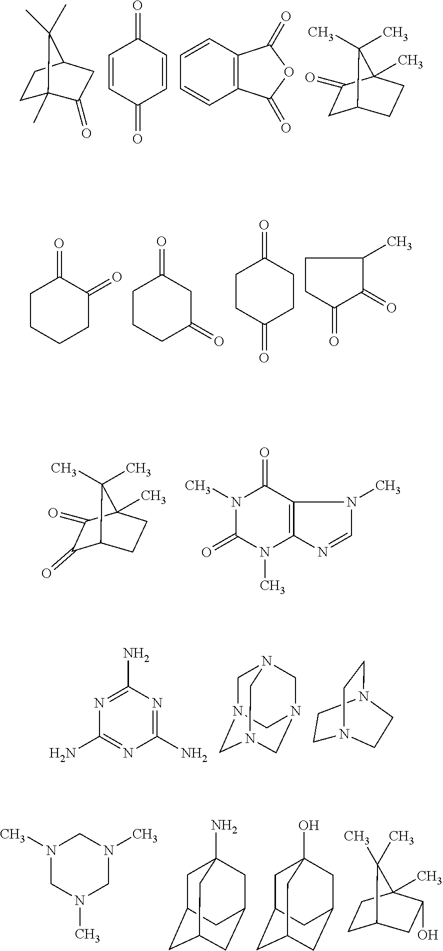

Further, the vaporization component (D) may be a low molecular weight compound having 2 or more and 25 or less carbon atoms. In this case, the vaporization component (D) is, for example, 1,2-ethanediol, 1,2-propanediol, 1,3-propanediol, 1,2-butanediol, 1,3-butanediol, 1,4-butanediol, 3-methyl-1,3-butanediol, 3-phenyl-1,3-butanediol, 1,2-pentanediol, 1,3-pentanediol, 2,4-pentanediol, 1,5-pentanediol, 1,2-hexanediol, 2,5-hexanediol, 2,4-diethyl-1,5-pentanediol, 2,4-dimethyl-2,4-pentanediol, 3-methyl-1, 5-pentanediol, diethylene glycol, diethanolamine, 1,3-cyclopentanediol, 1,2-cyclohexanediol, 1,3-cyclohexanediol, 1,4-cyclohexanediol, 4-methyl-1,2-cyclohexanediol, 4-methylcatechol, or the like. Preferably, the vaporization component (D) is 1,2-butanediol, 1,3-butanediol, 1,4-butanediol, 3-methyl-1,3-butanediol, or 3-phenyl-1,3-butanediol.

Further, the vaporization component (D) may be a polymer. In this case, the vaporization component (D) is, for example, polyethylene glycol, polypropylene glycol, polypropylene carbonate, polyethylene carbonate, polyethylene propylene glycol, polyacetal, or the like. Preferably, the vaporization component (D) is polyethylene glycol or polypropylene carbonate.

When the solidification component included in the substrate treatment solution according to an embodiment of the present invention does not satisfy the above condition (i) but satisfies the above condition (ii), and the solidification component (A) is the vaporization component (D), particular examples of the solidification component (A) are the same as those of the vaporization component (D), which is mentioned above.

### [1-5. Other Additive (E)]

The substrate treatment solution according to an embodiment of the present invention may further include the other additive (E). The other additive (E) is a compound different from the components (A) to (D), which are described above. The other additive (E) is preferably highly volatile. In particular, although the other additive (E) is preferably vaporized when the solidification component (A) is vaporized, or before or after the vaporization of the solidification component (A), the other additive (E) is not limited thereto. The content of other additives (E) included in the substrate treatment solution is 0 to 20% by mass, preferably 0 to 10% by mass, more preferably 0 to 5% by mass, based on the solidification component (A). It goes without saying that in an embodiment of the present invention, the substrate treatment solution includes an aspect in which the other additive (E) is not included (0% by mass).

The other additive (E) is particular explained below.

An example of the other additive (E) is a surfactant. When the substrate treatment solution includes a surfactant as the other additive (E), the applicability to the substrate can be improved. The content of the surfactant included in the substrate treatment solution is 0 to 2% by mass, preferably 0 to 1% by mass, and more preferably 0 to 0.5% by mass, based on the solidification component (A).

Any surfactant can be used. For example, an anionic surfactant, a cationic surfactant, or a nonionic surfactant can be used as the surfactant. More particularly, it is preferred that alkyl sulfonate, alkylbenzenesulfonic acid, and alkylbenzenesulfonate, laurylpyridinium chloride, laurylmethylammonium chloride, polyoxyethylene octyl ether, polyoxyethylene lauryl ether, or polyoxyethylene acetylenic glycol ether is used as the surfactant. In addition, as a nonionic surfactant, a nonionic alkyl ether-based surfactant manufactured by Nippon Nyukazai etc. is commercially available as the nonionic surfactant.

Further, another example of the other additive (E) is an antibacterial agent, a bactericidal agent, a preservative, or an antifungal agent. When the antibacterial agent, the bactericidal agent, the preservative, or the antifungal agent is included as other additives (E), the growth of bacteria or fungi in the substrate treatment solution can be prevented and changes in the substrate treating solution over time can be suppressed. The content of the antibacterial agent, the bactericidal agent, the preservative, or the antifungal agent included in the substrate treatment solution is 0 to 1% by mass, preferably 0 to 0.1% by mass, more preferably 0 to 0.01% by mass, based on the solidification component (A).

For example, alcohols such as phenoxyethanol or isothiazolones can be used as the antibacterial agent, the bactericidal agent, the preservative, or the antifungal agent. In addition, Bestside (trade name) manufactured by Nippon Soda Co., Ltd. is commercially available as the antibacterial agent, the bactericidal agent, the preservative agent, or the antifungal agent.

Furthermore, another example of the other additive (E) is an acid or a base. When the acid or the base is included as the other additive (E), the properties of the substrate treatment solution can be improved by adjusting the PH of the substrate treatment solution or adjusting the solubility of the above components (A) to (D) in the substrate treatment solution. The acid or the base may be prepared depending on the material of the substrate to which the substrate treatment solution is applied, and may be added to the substrate treatment solution. The content of the acid or the base included in the substrate treatment solution is 0 to 1% by mass, preferably 0 to 0.5% by mass, and more preferably 0 to 0.5% by mass, further preferably 0 to 2% by mass, based on the solidification component (A).

The acid or the base can be freely selected within a range not impairing the effects of the present invention. For example, carboxylic acids, amines, or ammonium salts can be used as the acid or the base. Carboxylic acids, amines, or ammonium salts referred to here include fatty acids, aromatic carboxylic acids, primary amines, secondary amines, tertiary amines, or ammonium compounds, which may be optionally replaced with any substituent. More particularly, formic acid, acetic acid, propionic acid, benzoic acid, phthalic acid, salicylic acid, lactic acid, malic acid, citric acid, oxalic acid, malonic acid, succinic acid, fumaric acid, maleic acid, aconite acid, glutaric acid, adipic acid, monoethanolamine, diethanolamine, triethanolamine, triisopropanolamine, or tetramethylammonium can be used as the acid or the base.

### [2. Use of Substrate Treatment Solution]

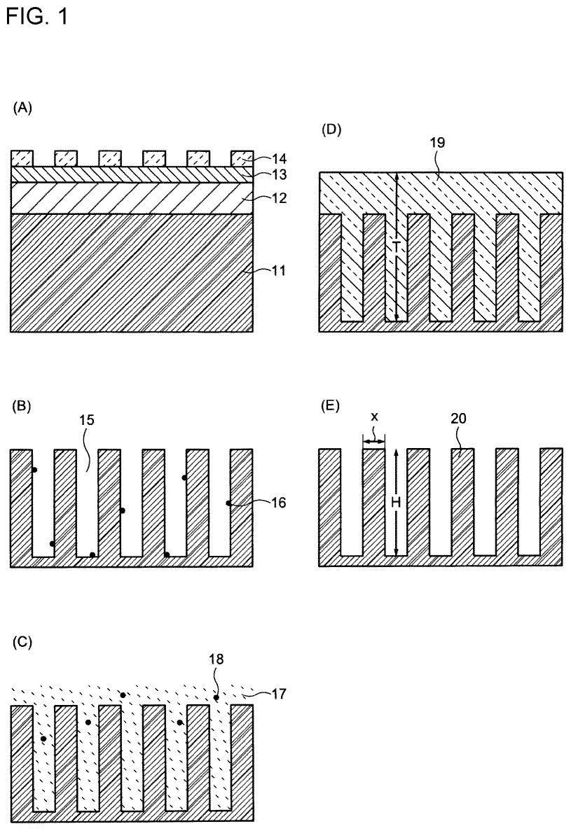

The use of the substrate treatment solution according to an embodiment of the present invention is described with reference to FIGS. 1(A) to 1(E).

FIGS. 1(A) to 1(E) are schematic cross-sectional views illustrating a method for forming a substrate pattern using a substrate treatment solution according to an embodiment of the present invention. FIGS. 1(A) to 1(E) sequentially illustrate steps of the method for forming a substrate pattern. The method for forming the substrate pattern can be freely selected from known methods such as dry etching. For example, Non-Patent Document 1 also discloses an example of a method for forming a substrate pattern. In addition, various pretreatments can be combined in forming the substrate pattern.

FIG. 1(A) shows a state in which a coated carbon film layer 12, a silicon-containing anti-reflective coating layer 13, and a resist pattern 14 are sequentially formed on a substrate 11.

The substrate 11 is a semiconductor wafer, a glass substrate for a liquid crystal display device, a glass substrate for an organic EL display device, a glass substrate for a plasma display, a substrate for an optical disk, a substrate for a magnetic disk, a substrate for a magneto-optical disk, a glass substrate for a photomask, or a substrate for a solar cell, etc. The substrate 11 may be an unprocessed substrate (for example, a bare wafer) or a processed substrate (for example, a patterned substrate). That is, a conductive film, wiring, a semiconductor element, or the like may be formed on the substrate 11. The substrate 11 may have a structure in which a plurality of layers are laminated. The substrate 11 is preferably a semiconductor. The semiconductor may be composed of an oxide, a nitride, a metal, or any combination thereof. Therefore, although the material of the substrate 11 is not particularly limited, the material of the substrate 11 is, for example, Si, Ge, SiGe, SiO₂, TiO₂, Al₂O₃, SiON, HfO₂, Ta₂O₅, HfSiO₄, Y₂O₃, GaN, TiN, TaN, Si₃N₄, NbN, Cu, Ta, W, Hf, or Al.

The coated carbon film layer 12 includes a coated carbon film (also referred to as a coated C film or Spin On Carbon film). The coated carbon film layer 12 is formed by applying a conventionally known method such as spin coating, and performing pre-baking. Further, the coated carbon film layer 12 may be formed by a CVD (chemical vapor deposition) method or an ALD (atomic layer deposition) method.

The silicon-containing anti-reflective coating layer 13 includes a silicon-containing anti-reflection film (also referred to as a Si-ARC film). The silicon-containing anti-reflective coating layer 13 is formed by applying a conventionally known method such as spin coating, and performing pre-baking. By forming the silicon-containing anti-reflective coating layer 13, the cross-sectional shape and exposure margin can be improved. In addition, when the silicon-containing anti-reflective coating layer 13 is used as an etching mask, the silicon-containing anti-reflection film layer 13 preferably has etching resistance.

The resist pattern 14 can be formed by combining known methods. For example, a method for forming the resist pattern 14 is disclosed in Patent Document 3.

In etching the substrate 11, the silicon-containing anti-reflective coating layer 13 may be etched using the resist pattern 14 as a mask, and then the coated carbon film layer 12 and the substrate 11 may be etched using the silicon-containing anti-reflective coating layer 13 as a mask. After etching the silicon-containing anti-reflective coating layer 13 and the coated carbon film layer 12 using the resist pattern 14 as a mask, the substrate 11 may be etched using the silicon-containing anti-reflective coating layer 13 and the coated carbon film layer 12 as a mask. Alternatively, the silicon-containing anti-reflective coating layer 13, the coated carbon film layer 12, and the substrate 11 may be successively etched using the resist pattern 14 as a mask. In addition, the etching may be wet etching or dry etching.

FIG. 1(B) shows a state in which the substrate 11 is dry-etched and a gap 15 is formed on the surface of the substrate 11. Although the type of gases for dry etching is not particularly limited, a fluorocarbon-based gas is generally used. As shown in FIG. 1(B), a residue (debris) 16 remains in the gap 15 after dry etching.

FIG. 1(C) shows a state in which the etched substrate 11 is cleaned with the cleaning liquid 17. The cleaning method using the cleaning liquid 17 may be a known method, such as a coating method, a dropping method, a liquid immersion method, or a combination thereof. The residue 18 is removed by cleaning with the cleaning liquid 17. The cleaning liquid 17 is preferably an organic solvent, more preferably IPA.

FIG. 1D shows a state in which the gap 15 is filled with the substrate treatment solution 19. In particular, in FIG. 1D, a film of the substrate treatment solution 19 is formed to cover the gap 15. The substrate treatment solution 19 is applied (including dripping or immersion) while the cleaning liquid 17 remains in the gap 15. Although the application of the substrate treatment solution 19 is not particularly limited, the application can be performed, for example, by any method such as a method of dropping the substrate treatment solution 19 on the surface of the substrate 11 to spread the substrate treatment solution 10 while rotating the substrate 11 at 1 to 3000 rpm, a method of dropping the substrate treatment solution 10 on the surface of the substrate 11 that is stationary and then rotating the substrate 19 to spread the substrate treatment solution 19, or a method of supplying the substrate treatment solution 19 by spraying or blasting, or the like. Among these methods, the preferred method is to drop and spread the substrate treatment solution 19 on the surface of the substrate 11 while rotating the substrate 11 at 1 to 3000 rpm, or to drop the substrate treatment solution 19 on the surface of the substrate 11 that is stationary and then rotating the substrate 19 to spread the substrate treatment solution 19. At this time, at least a portion of the cleaning liquid 17 in the gap 15 is replaced with the substrate treatment solution 19, and the substrate treatment solution 19 is filled in the gap 15. In order to fully exhibit the effects of the present invention, it is preferable that the cleaning liquid 17 be sufficiently replaced by the substrate treatment solution 19.

Washing may also be performed by multiple steps. For example, after applying a cleaning liquid (such as an acid or a base) that dissolves and removes inorganic substances, a cleaning liquid (such as deionized water or an organic solvent) that is highly compatible with the substrate treatment solution 19 may be applied. Even in this case, it is preferable that the cleaning liquid present in the gap 15 be sufficiently replaced by the substrate treatment solution 19.

After the above steps, the substrate 11 may be rotated at more than 50 rpm and lower than 5000 rpm. By this rotation, the excess organic solvent and water in the substrate treatment solution 19 are removed from the substrate 11, but at least a part of the solidification component (A) remains. Since not all of the components of the substrate treatment solution 19 are removed from the gap 15, a film is formed and pattern collapse can be prevented.

The thickness T of the film formed by the substrate treatment solution 19 is, for example, 0.02 to 5 μm, preferably 0.05 to 4 μm, and more preferably 0.1 to 3 μm. Further, the relationship between the thickness T of the film and the height H of the pattern 20 described later satisfies, for example, 1H≤T≤5H, preferably 1.2H≤T≤4H, more preferably 1.5H≤T≤3H. When the film thickness of a film formed using a conventional substrate treatment solution increases, there is a problem that cracks occur in the film. That is, the conventional film has a large dependence on the film thickness and the process window was narrow. Although not to be bound by theory, in an aspect of the present invention, the film formed by the substrate treatment solution 19 is a film made of the solidification component (A) having the plastic property, and has high toughness, so that it is considered that cracks are unlikely to occur even when the film is thick. Therefore, it is considered that the film formed by the substrate treatment solution 19 has a wide process window and can prevent pattern collapse even in the case of a thick film.

FIG. 1(E) shows a state in which the pattern 20 formed with the substrate treatment solution 19 filled in the gap 15 is removed. The substrate treatment solution 19 can also be removed by heating, air drying (spraying), rotation, standing still, or a combination thereof. Any method may be used to remove the substrate treatment solution 19 as long as the shape of the pattern 20 is not damaged. In removing the substrate treatment solution 19 by heating, although the heating time is not particularly limited, for example, 0 to 180 seconds, preferably 10 to 120 seconds, and more preferably 10 to 90 seconds is preferred. The removal of the substrate treatment solution 19 by air drying can be performed by holding the pattern 20 in an air stream. At this time, the airflow may be at positive pressure or may be at negative pressure. In particular, airflow can be generated by blowing gas. In this case, the gas to be blown is not particularly limited. Although it is possible to use a gas such as air, it is preferable to use an inert gas such as argon gas or nitrogen gas. The flow rate of the airflow is not particularly limited, and the conditions under which the substrate treatment solution 19 is removed are appropriately selected. In removing the substrate treatment solution 19, it is preferable that the humidity of the atmosphere or the gas forming the airflow is low. For example, the humidity of the gas is 10% or less, preferably 5% or less, more preferably 1% or less, particularly preferably 0.1% or less. In removing the substrate treatment solution 19 by rotation, although the rotation speed and rotation time of the substrate are not particularly limited, for example, 20 to 2000 rpm for 30 to 300 seconds is preferred.

Here, as shown in FIG. 1(E), the line width of the pattern 20 is represented by x and the height is represented by H. The aspect ratio of the pattern 20 is expressed as H/x. For a range in which the above-described substrate pattern formation method can be effectively applied, the pattern height H is, for example, 0.01 to 6 μm or less, preferably 0.05 to 5 μm, and more preferably 0.1 to 3 μm. Further, the aspect ratio H/x is, for example, 5 to 25, preferably 15 to 22.

In the method for forming the substrate pattern using the substrate treatment solution according to an embodiment of the present invention, even when the pattern is minute, the collapse rate of the substrate pattern can be suppressed. For example, a pillar pattern in which the central part of the cylinder is thinner than the bottom part and/or top part is likely to collapse. However, even for such a pillar pattern, it is possible to clean the substrate pattern while suppressing the collapse rate by using the above-described method for forming the substrate pattern.

Although the line space pattern, which is a wall structure, is considered to be less likely to collapse than the pillar pattern, the collapse rate can be further reduced by using the above-described method for forming the substrate pattern.

A device can be manufactured by further processing the above-described pattern 20. The device includes, for example, a semiconductor device, a liquid crystal display device, an organic EL display device, a plasma display device, and a solar cell device. The device is preferably the semiconductor. Known methods can be used for these processing. After forming a device, if necessary, the substrate can be cut into chips, connected to a lead frame, and packaged with resin. An example of the packaged device is the semiconductor.

### EXAMPLES

In the following description, the substrate treatment solution according to an embodiment of the present invention is described in more detail based on examples. In addition, the substrate treatment solution according to an embodiment of the present invention is not limited to the following examples.

### [Preparation of Example 1]

2,2-dimethyl-1-propanol (S1) as the solidification component (A) is added to IPA as the solvent (C) in an amount of 10% by mass, based on the prepared substrate treatment solution. The vessel is capped and stirring is performed overnight, and it is visually confirmed that the solute is dissolved. The solution obtained above is filtered through a filter having a pore size of 0.1 μm to obtain a substrate treatment solution (Example 1).

### [Preparation of Examples 2 to 15 and Comparative Examples 1 and 2]

As shown in Table 1, substrate treatment solutions (Examples 2 to 15, Comparative Examples 1 and 2) are prepared and obtained in the same manner as Example 1, except that the types and concentrations of the solidification component (A), surface modification component (B), and solvent (C) are changed. The concentration of the surface modification component (B) is based on the prepared substrate treatment solution.

TABLE 1

| | | (A) | | | (B) |
|---|---|---|---|---|---|
| | | concen- | | surface | concen- |
| | solidifying | tration | | modification | tration |
| | component | (% by | solvent | component | (% by |
| | (A) | mass) | (C) | (B) | mass) |
| Example1 | S1 | 10 | IPA | — | — |
| Example2 | S1 | 20 | IPA | — | — |
| Example3 | S1 | 30 | IPA | — | — |
| Example4 | S2 | 20 | IPA | — | — |
| Example5 | S3 | 20 | IPA | — | — |
| Example6 | S4 | 20 | IPA | — | — |
| Example7 | S5 | 20 | IPA | — | — |
| Example8 | S2 | 20 | DIW | — | — |
| Example9 | S1 | 20 | IPA | F1 | 0.1 |
| Example10 | S1 | 20 | IPA | F2 | 0.1 |
| Example11 | S1 | 20 | IPA | F3 | 0.1 |
| Example12 | S1 | 20 | IPA | F4 | 0.1 |
| Example13 | S2 | 20 | IPA | F1 | 0.1 |
| Example14 | S2 | 20 | IPA | F2 | 0.1 |
| Example15 | S2 | 20 | DIW | F4 | 0.1 |
| Comparative | S6 | 20 | IPA | — | — |
| Example1 | | | | | |
| Comparative | S7 | 20 | IPA | — | — |
| Example2 | | | | | |

Here, S1 in Table 1 is 2,2-dimethyl-1-propanol, S2 is 2,2-dimethyl-1,3-propanediol, S3 is 2,2-dimethyl-1,3-propanediamine, S4 is 2,2-dimethylpropionic acid, S5 is DL-pantolactone, S6 is cyclohexanone oxime, and S7 is cyclohexane. F1 in Table 1 is pentadecafluorotriethylamine, F2 is 2,2,3,4,4,4-hexafluoro-1-butanol, F3 is 2,2,3,3,3-pentafluoro-1-propanol, and F4 is bis(nonafluorobutanesulfonyl)imide.

### [Evaluation of Formation of Plastic Crystal Layer]

A wafer on which a pillar pattern is formed (hereinafter referred to as a pattern wafer) is attached to an MS-A150 spin coater (Mikasa), and 2 cc of a substrate treatment solution is dropped onto the pattern wafer and spin coated at 1,000 rpm for 20 seconds. The pattern wafer has a pillar pattern formed on a silicon wafer with a diameter of about 30 nm at the top, a diameter of about 65 nm at the bottom, and a height of about 600 nm (provided from the Interuniversity Microelectronics Centre (IMEC)), and is used by cutting into approximately 3 cm squares. It is visually confirmed whether a plastic crystal layer is formed from the solidification component (A) in the substrate treatment solution, or not formed. The evaluation criteria are as follows. However, in Comparative Example 2, the formation of a solid film is not confirmed, so no data can be obtained.

A: A plastic crystal layer is formed.

B: A plastic crystal layer is not formed.

### [Crack Evaluation]

In order to prepare a sample substrate for crack evaluation, the following treatment is performed using the same pattern wafer used to evaluate the formation of the plastic crystal layer. The pattern wafer is attached to an MS-A150 spin coater, 2 cc of substrate treatment solution is dropped onto the patterned wafer, and spin coated at 1,000 rpm for 20 seconds. Immediately after spin coating, the patterned wafer is placed on a metal plate cooled to −120° C. to cool the solid film and suppress sublimation of the solid film. The upper surface of the sample substrate is observed using a cryo-SEM (Helios NanoLab 650, Thermo Scientific) at a magnification of 3K within a range that can be seen without moving, and the presence or absence of cracks in the solid film is evaluated. The evaluation criteria are as follows. However, in Comparative Example 2, the formation of a solid film is not confirmed, so no data can be obtained.

A: Cracks are not discovered.

B: Cracks are discovered.

### [Measurement of Film Thickness in Crack Evaluation]

A wafer section of the sample substrate for crack evaluation is prepared. The film thickness is measured by observing the cross section of the wafer using a cryo-SEM at a magnification of 20K in a visible range without moving. In addition, in Comparative Example 2, the formation of a solid film is not confirmed, so no data can be obtained.

### [Remaining Film Evaluation]

In order to prepare a sample substrate for evaluation of remaining film, the following treatment is performed using the same pattern wafer used to evaluate the formation of the plastic crystal layer. The pattern wafer is attached to an MS-A150 spin coater, 2 cc of the substrate treatment solution is dropped onto the patterned wafer, and spin coated at 1,000 rpm for 20 seconds. Thereafter, the pattern wafer is immediately heated on a hot plate at 65° C. for 120 seconds to sublimate and remove the solid film. A wafer section of the sample substrate is prepared. The cross section of the wafer is observed with a SEM (SU8200, Hitachi High Technologies) at a magnification of 20K in a range that can be visually recognized without moving, and the presence or absence of remaining film is evaluated. The evaluation criteria are as follows. However, in Comparative Example 2, the formation of a solid film was not confirmed, so no data can be obtained.

A: No remaining film is observed.

B: Remaining film is confirmed.

### [Evaluation of Collapse Rate of Substrate Pattern]

A sample substrate is prepared similar to the sample substrate for remaining film evaluation. The upper surface of the sample substrate is observed using a SEM (SU8200) at a magnification of 10K in a range that can be visually recognized without moving, and the collapse rate of the substrate pattern is evaluated. The collapse rate is calculated by dividing the number of collapsed patterns among the substrate patterns in the observed image by the total number of patterns, and multiplying the result by 100. The evaluation criteria are as follows.

A: The collapse rate is less than 1%.

B: The collapse rate is 1% or more and less than 5%.

C: The collapse rate is 5% or more.

### [Total Evaluation]

A total evaluation is made based on the above evaluation. The evaluation criteria are as follows.

A: The remaining film evaluation is A, and the collapse rate evaluation is A.

B: The remaining film evaluation is A, and the collapse rate evaluation is B.

C: The remaining film evaluation is B, or the remaining film evaluation is A and the collapse rate evaluation is C.

Table 2 shows the results of evaluation of the plastic crystal layer evaluation, crack evaluation, film thickness, remaining film evaluation, evaluation of collapse rate of substrate pattern, and total evaluation described above.

TABLE 2

| | | | | | evalu- | |
|---|---|---|---|---|---|---|
| | | | | | ation | |
| | | | | | of | |
| | | | | remain- | collapse | |
| | evaluation | | | ing | ratio | |
| | of plastic | crack | thick- | film | of | total |
| | crystal | evalu- | ness | evalu- | substrate | evalu- |
| | layer | ation | (μm) | ation | pattern | ation |
| Example1 | A | | 0.8 | A | B | B |
| Example2 | A | A | 1.8 | A | B | B |
| Example3 | A | A | 3.5 | A | B | B |
| Example4 | A | A | 2.4 | A | B | B |
| Example5 | A | A | 2.1 | A | B | B |
| Example6 | A | A | 2.2 | A | B | B |
| Example7 | A | A | 2.0 | A | B | B |
| Example8 | A | A | 2.0 | A | B | B |
| Example9 | A | A | 1.8 | A | A | A |
| Example10 | A | A | 1.8 | A | A | A |
| Example11 | A | A | 1.8 | A | A | A |
| Example12 | A | A | 1.8 | A | A | A |
| Example13 | A | A | 2.4 | A | A | A |
| Example14 | A | A | 2.4 | A | A | A |
| Example15 | A | A | 2.0 | A | A | A |
| Comparative | B | B | 1.3 | A | C | C |
| Example1 | | | | | | |
| Comparative | — | — | — | — | C | C |
| Example2 | | | | | | |

As can be seen from Table 2, it can be seen that Examples 1 to 15 are better as substrate treatment solutions than Comparative Examples 1 and 2.

### EXPLANATION OF SYMBOLS

11: substrate
12: coated carbon film layer
13: silicon-containing anti-reflective coating layer
14: resist pattern
15: gap
16: residue (debris)
17: cleaning liquid
18: residue
19: substrate treatment solution
20: pattern

1. A substrate treatment solution comprising a solidification component, wherein at least either the following condition (i) or condition (ii) is satisfied:
(i) the solidification component is a plastic crystal compound having a melting point of 20° C. or more and 200° C. or less, and
(ii) the substrate treatment solution further comprises a surface modification component represented by the following general formula (I), 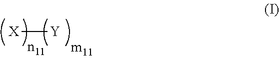
wherein X is each independently one of the group consisting of a tertiary amine, a secondary amine, a primary amine, —OH, —SO₂—NH—SO₂—, —CO—NH₂, —COOH, —CHO, —SO₃H, —CO—NH—CO—, and —CO—NH—SO₂—,
wherein Y is each independently H, fluoroalkyl having C₁₋₁₀, or fluoroaryl having C₅₋₂₀, and at least one of Y is fluoroalkyl having C₁₋₁₀ or fluoroaryl having C₅₋₂₀,
wherein n₁₁ is 1, 2 or 3,
wherein m₁₁ is 1, 2 or 3, and
wherein at least one of n₁₁ and m₁₁ is 1.

2. The substrate treatment solution according to claim 1, wherein the substrate treatment solution is not cooled above a temperature that is 5° C. lower than a freezing point of the solidification component and below a temperature of the freezing point of the solidification component.

3. The substrate treatment solution according to claim 1, wherein the solidification component has a molecular weight of 58 or more and 200 or less.

4. The substrate treatment solution according to claim 1, wherein a content of the solidification component is 1% by mass or more and 50% by mass or less based on the substrate treatment solution.

5. The substrate treatment solution according to claim 1, wherein a content of the surface modification component is 0.01% by mass or more and 1.0% by mass or less based on the substrate treatment solution.

6. The substrate treatment solution according to claim 1, further comprising a solvent,
wherein the solvent comprises an organic solvent comprising at least one selected from the group consisting of alcohols, alkanes, ethers, lactic esters, acetic esters, aromatic hydrocarbons, ketones, amides, and lactones, and/or a water.

7. The substrate treatment solution according to claim 1, wherein the substrate treatment solution is used for replacing a cleaning liquid that remains on the substrate when a substrate pattern on the substrate is cleaned with the cleaning liquid.

8. The substrate treatment solution according to claim 1,
wherein a film is formed using the substrate treatment solution, and then the film is removed from a substrate pattern by vaporizing the solidification component, and
wherein the vaporization is a sublimation, or is performed by at least by one step selected from the group consisting of heating a substrate, blowing a gas, and rotating the substrate when the film formed using the substrate treatment solution is removed.

9. The substrate treatment solution according claim 1,
wherein the substrate treatment solution is applied on a pattern of a substrate to form a film, and
wherein a thickness T of the film and a height H of the pattern satisfy a relational equation 1H≤T≤5H.
